(19) United States
(12) Patent Application Publication
(10) Pub. No.: US 2025/0300527 A1
(43) Pub. Date: Sep. 25, 2025

(54) MOTOR, A COOLING CONTROL METHOD THEREOF, AND A VEHICLE INCLUDING THE SAME

(71) Applicants: HYUNDAI MOTOR COMPANY, Seoul (KR); KIA CORPORATION, Seoul (KR)

(72) Inventors: Hoo Dam Lee, Seoul (KR); Tae Gyu Lee, Seoul (KR); Kyung Sik Choi, Seoul (KR); Hyung Kwan Jang, Uijeongbu-si (KR); Jun Hyeok Choi, Suwon-si (KR); Byung Ho Min, Suwon-si (KR); Woo Ju Lee, Hwaseong-si (KR)

(73) Assignees: HYUNDAI MOTOR COMPANY, Seoul (KR); KIA CORPORATION, Seoul (KR)

(21) Appl. No.: 18/919,050

(22) Filed: Oct. 17, 2024

(30) Foreign Application Priority Data
Mar. 21, 2024 (KR) 10-2024-0039400

(51) Int. Cl. H02K 9/22; H02K 11/30; H02K 21/16; H10N 10/17

(52) U.S. Cl. CPC H02K 9/22; H02K 11/30; H02K 21/16; H10N 10/17

(57) ABSTRACT

A motor includes a stator provided inside a housing and having a plurality of stator coils repeatedly disposed in a circumferential direction. The motor also includes a thermoelectric module provided in the housing and configured to cool the plurality of stator coils. The thermoelectric module includes a substrate, at least one pair of an N-type pellet and a P-type pellet alternately mounted on the substrate, and a connection electrode configured to connect the N-type pellet and the P-type pellet to each other on a side.

### CROSS-REFERENCE TO RELATED APPLICATION(S)

This application claims benefit of and priority to Korean Patent Application No. 10-2024-0039400 filed on Mar. 21, 2024 in the Korean Intellectual Property Office, the disclosure of which is incorporated herein by reference in its entirety.

### BACKGROUND

### 1. Field

The present disclosure relates to a motor, a method of controlling cooling thereof, and a mobility device including the same.

### 2. Description of Related Art

In general, electric motors may be divided into direct current (DC) motors and alternating current (AC) motors based on a power source used. AC motors may be divided into synchronous motors and induction motors depending on structures thereof. Synchronous s motors have high efficiency and are relatively easy to control, while being difficult to manufacture and being relatively high in price. Induction motors may be widely used due to a simple structure thereof, may be resistant to external shocks, and may be inexpensive.

Recently, as research into and development of electric vehicles has accelerated, demand for electric motors has also increased significantly. Electric motors used as driving sources for electric vehicles are usually high-speed, high-output motors.

Mobility devices, including hybrid electric vehicles, urban air mobility, and the like may be partially or fully driven by motors rather than internal combustion engines of the related art. As a motor of such a mobility device, the stator may be provided with a stator coil wound with a wire such as a coil or the like, and the rotor may be provided with a rotor magnetic material such as a permanent magnet or the like.

However, there may be a problem in which performance of a motor may be reduced due to heat generated from copper windings commonly used as stator coils, or the like. A large amount of research into technology to effectively cool the motor to reduce a resulting decrease in motor efficiency is being undertaken. However, the reality is that there are many doubts about effectiveness thereof. The subject matter described in this background section is intended to promote an understanding of the background of the disclosure and thus may include subject matter that is not already known to those of ordinary skill in the art.

### SUMMARY

An aspect of the present disclosure is to provide a structure of a motor that may actively control heat generation of the motor that may be generated by a stator coil.

According to an aspect of the present disclosure, a motor includes a stator provided inside a housing and having a plurality of stator coils repeatedly disposed in a circumferential direction. The motor further includes a thermoelectric module provided in the housing and configured to cool the plurality of stator coils. The thermoelectric module includes a substrate, at least one pair of an N-type pellet and a P-type pellet alternately mounted on the substrate, and a connection electrode configured to connect the N-type pellet and the P-type pellet to each other on a side.

The motor may include a rotor provided inside the stator, rotatable about a rotation axis, and having a magnetic body configured to interact with at least one of the plurality of stator coils and generate rotational force.

The motor may include an insulating layer provided on an upper surface of the substrate. The N-type pellet and the P-type pellet are mounted on the upper surface of the substrate.

The N-type pellet and the P-type pellet may be covered with an insulating layer except for portions thereof connected to the connection electrode.

The N-type pellet, the P-type pellet, and the connection electrode may be provided with a metal solder joint therebetween.

The thermoelectric module may include the N-type pellet and the P-type pellet alternately mounted on the substrate in the circumferential direction and an optical axis direction.

A plurality of connection electrodes may be alternately provided on both sides of the N-type pellet and the P-type pellet and may be connected in series.

The thermoelectric module may include the N-type pellet and the P-type pellet mounted on a plurality of separated substrates. The plurality of separated substrates may be disposed at regular intervals in the circumferential direction.

The thermoelectric module may be inserted into a slot provided in the housing.

The thermoelectric module may be attached to an outer surface of the housing.

The substrate may be a flexible substrate.

According to an aspect of the present disclosure, a method of controlling cooling of a motor includes performing a sensing operation by detecting a temperature of a housing of the motor. The method further includes performing a control operation by comparing the temperature of the housing detected in the sensing operation with a set temperature. The control operation is further performed by operating a thermoelectric module provided in the housing by selecting either a thermoelectric power generation mode or a Peltier mode as a cooling mode.

The set temperature may be selected from 90 to 110 degrees.

The method may further include operating the thermoelectric module in the thermoelectric power generation mode when the temperature detected in the sensing operation is equal to or lower than the set temperature. The method may further include operating the thermoelectric module in the Peltier mode as the cooling mode when the temperature detected in the sensing operation exceeds the set temperature.

The method may further include storing, in a battery electricity generated when the control unit operates the thermoelectric module in the thermoelectric power generation mode. The method may further include using the electricity stored in the battery when the control unit operates the thermoelectric module in the Peltier mode as the cooling mode.

According to an aspect of the present disclosure, a mobility device includes a body; at least one driving unit provided on the body; a battery provided in the body; and the motor according to an embodiment, configured to be connected to the battery and provide driving force to the at least one driving unit.

### BRIEF DESCRIPTION OF DRAWINGS

The above and other aspects, features, and advantages of the present disclosure should be more clearly understood from the following detailed description, taken in conjunction with the accompanying drawings, in which:

FIG. 1 is a combined perspective view of a motor according to an embodiment;

FIG. 2 is an exploded perspective view of a motor according to an embodiment;

FIG. 3 is a cross-sectional view of a motor according to an embodiment;

FIGS. 4 and 5 are cross-sectional views of a motor according to another embodiment;

FIG. 6 is a perspective view illustrating an example of a thermoelectric module applied to a motor according to an embodiment;

FIG. 7 is a plan view illustrating an example of a thermoelectric module applied to a motor according to an embodiment;

FIG. 8 is a side view illustrating an example of a thermoelectric module applied to a motor according to an embodiment;

FIG. 9 is a detailed side view illustrating an example of a thermoelectric module applied to a motor according to an embodiment and an enlarged view of a unit pellet;

FIGS. 10 and 11 are plan views illustrating an example of a thermoelectric module applied to a motor according to another embodiment;

FIG. 12 is a conceptual diagram of a temperature control device of a motor according to an embodiment;

FIG. 13 is a conceptual diagram illustrating a method of controlling temperature of a motor according to an embodiment; and

FIGS. 14, 15, and 16 are perspective views illustrating an example of a mobility device to which a motor according to an embodiment is applied.

### DETAILED DESCRIPTION

Because the present disclosure may make various changes and have various embodiments, specific embodiments are illustrated in the drawings and described in detail. However, this is not intended to limit the present disclosure to specific embodiments. Instead, it should be understood to include all changes, equivalents, and substitutes included in the spirit and technical scope of the present disclosure.

Terms, such as first, second, and the like, may be used to describe various components, but the components should not be limited by the terms. The above terms are used only for the purpose of distinguishing one component from another. For example, a first component may be named a second component, and similarly, the second component may also be named a first component without departing from the scope of the present disclosure. The term ‘and/or’ includes any combination of a plurality of related stated items or any of a plurality of related stated items.

Terms, such as “unit,” “part,” “portion,” and the like, may be used to describe various components, but the components should not be limited by the terms. The above term may refer to not only a physically/visually distinct configuration but also a term that describes the function or configuration of the corresponding part even if the distinction/division is not clear.

The terms used in the present disclosure are only used to describe specific embodiments and are not intended to limit the present disclosure. Singular expressions include plural expressions unless the context clearly dictates otherwise. In the present disclosure, terms, such as “comprise,” “include” and “have,” are intended to designate the presence of features, numbers, steps, operations, components, parts, or combinations thereof described in the present disclosure. It should be understood that the terms do not exclude the presence or addition of one or more other features, numbers, steps, operations, components, parts, or combinations thereof.

Unless otherwise defined, all terms used herein, including technical or scientific terms, have the same meaning as commonly understood by a person of ordinary skill in the technical field to which the present disclosure pertains. Terms defined in commonly used dictionaries should be interpreted as having meanings consistent with the meanings in the context of the relevant technology. Unless explicitly defined in this application, to the terms should not be interpreted in an idealistic or overly formal sense.

In the present disclosures, a mobility device may move in space related to land, underground, air, space, sea, and/or underwater, depending on the space in which it moves. Aboveground or underground mobility devices may be provided in the form of, for example, vehicles, robots, or the like. Air and space mobility devices are known as air mobility devices and, for example, may be provided in the form of a typical fixed-wing or rotary-wing aircraft, the recently actively developed Advanced Air Mobility (AAM), unmanned aerial vehicles or drones, rockets, means of transportation mounted on artificial satellites, and the like. The sea or underwater mobility device may be, for example, a ship, a submarine, or the like. The mobility device is not limited to a specific space and may be a mobile body that may move through all of the above-mentioned spaces, for example, a mobile body that may move between multiple spaces. For example, the mobility device may be an amphibious vehicle, a flying vehicle, or the like.

In the description below, the terms “anterior,” “posterior,” “lateral,” “front,” “back,” “up/down,” “above,” “upper,” “top,” “below,” “lower,” “bottom,” “left/right,” and the like, used in relation to direction, are defined based on the vehicle or body of the car. In addition, terms, such as first, second and the like, may be used to describe various components. However, these components are not limited in order, size, location, or importance by terms such as first, second and the like and are named only for the purpose of distinguishing one component from other components. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

Hereinafter, embodiments are described in more detail with reference to the attached drawings.

As is well known, a motor includes a stator and a rotor, and the rotor is configured to rotate by electromagnetic interaction between the stator and the rotor. The motor includes a Permanent Magnet Synchronous Motor (PMSM) in which a magnetic material (permanent magnets using rare earth metals or the like) or superconducting wires (or copper, aluminum or the like being also usable) is used in the rotor. The motor also includes a Wound Field Synchronous Motor (WFSM) in which a field coil is wound around the rotor.

In addition, the motor has a plurality of stator coils repeatedly disposed in the circumferential direction on the stator, and there is a problem that the performance of the motor may be reduced due to heat generated from copper windings commonly used as stator coils (this is not limited, and the stator coil may be formed of various magnetic materials such as copper), or the like. The present disclosure seeks to prevent this problem through an active cooling structure using thermoelectric elements.

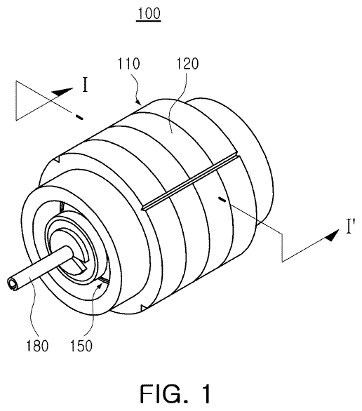

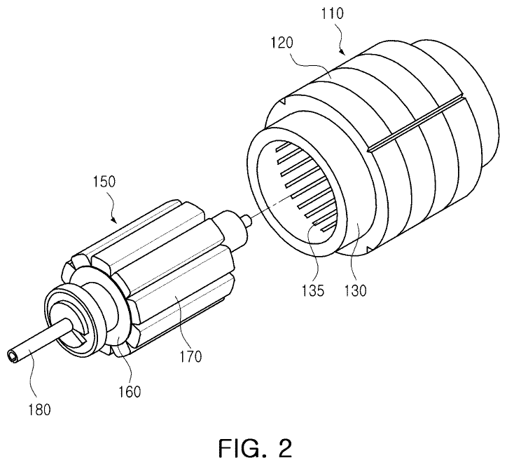

Referring to FIGS. 1 and 2, a motor 100 according to an embodiment may include a stator 110 and a rotor 150. The rotor 150 is fixedly installed on a rotation axis 180. The rotor 150 may rotate around the rotation axis 180 together with the rotation axis 180 inside the stator 110.

On the other hand, a structure in which a stator is provided inside the rotor is also included in an embodiment of the present disclosure. For example, the stator 110 may be provided in a cylinder or a cylindrical shape. The rotor 150 is provided in a cylindrical shape to surround the outer side of the stator 110 and may have a structure in which the rotor 150 surrounding the outside of the stator 110 rotates around a rotation axis. Below, for convenience of explanation, the description focuses on the structure in which the rotor 150 is provided inside the stator 110.

Hereinafter, the direction in which the rotation axis 180 extends is defined as the axial direction, the direction perpendicular to the rotation axis 180 is defined as the radial direction, and the direction in which the rotor 150 rotates around the rotation axis 180 is defined as the circumferential direction.

The motor 100 of this embodiment may have a stator coil 135 on the stator 110 and may have a magnetic body 170 that interacts with the stator coil 135 to generate rotational force, on the rotor 150. The magnetic body 170 may be a permanent magnet (rare earth metal or the like), a superconducting wire, a copper or aluminum wire, or the like.

An air gap is provided between the stator 110 and the rotor 150 to facilitate rotation of the rotor 150. Accordingly, a magnetic gap length may be formed between the stator 110 and the rotor 150.

The motor 100 of this embodiment may include the stator 110 including a housing 120 having a plurality of stator coils 135 repeatedly disposed in the circumferential direction. The motor 100 may also include the rotor 150 provided to be rotatable about the rotation axis 180 inside the stator 110 and having a rotor body 160 that includes the magnetic body 170 interacting with the stator coil 135.

The stator coil 135 may be provided on a stator body 130 provided inside the housing 120.

The stator 110 may include the housing 120 having a cylindrical shape and stator coils 135 repeatedly provided inside the housing 120 in the circumferential direction. The motor 100 of this embodiment may be implemented as a motor with various phases depending on the arrangement of the stator coil 135, such as a 3-phase, 4-phase, or 5-phase motor.

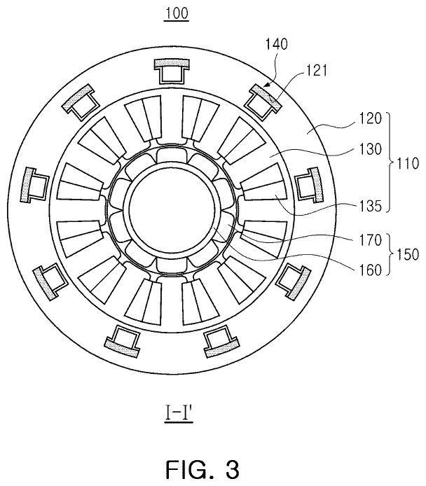

Referring to FIGS. 3, 4, and 5, the motor 100 according to an embodiment has an active cooling structure of the motor. Specifically, the motor 100 may include a stator 110 having a housing 120 and a plurality of stator coils 135 provided inside the housing 120 and repeatedly disposed in the circumferential direction. The motor 100 may also include a thermoelectric module 140 provided in the housing 120 to cool the plurality of stator coils 135.

The thermoelectric module 140 may harvest energy through heat exchange from the energy generated by copper loss (reduction in motor efficiency due to heat generation from the copper winding) inside the motor using a thermoelectric element (for example, BiTe system, etc.). The thermoelectric module 140 is a device that may cool the motor by applying electrical energy when the motor's temperature rises. A thermoelectric element may refer to a semiconductor element, and in the present disclosure, the thermoelectric element is referred to as an N-type pellet or a P-type pellet.

When heat is applied to one side of the thermoelectric module 140, a temperature difference occurs between both ends of the N-type and P-type pellets, and electrons are generated due to the temperature difference to generate power. When electricity is passed through N-type and P-type pellets, a heat flow is generated by the flow of electrons, causing one side to become cold and the other side to become hot.

Accordingly, in the present disclosure, when the motor becomes hot to some extent due to operation, the thermoelectric power generation effect is used to generate power using the thermoelectric module 140 and then store the electricity in the battery (in this case, it is heated to a level that has little effect on the operation of the motor). Alternatively, in the case in which the motor becomes too hot and needs to be cooled, the thermoelectric module may be actively used in cooling mode by the Peltier effect using electricity stored in the battery to cool the motor. In detail, the power generation mode that produces power using the thermoelectric module 140 and the Peltier mode (cooling mode) that uses stored electricity for cooling may be selected and actively utilized based on the situation.

Referring to FIGS. 3, 4, and 5, an embodiment of the thermoelectric module 140 provided in the motor 100 according to an embodiment is provided.

Referring to FIG. 3, the thermoelectric module 140 of this embodiment may be inserted into a groove provided in the housing 120, for example, a slot 121. Also, considering that a plurality of stator coils 135 are provided repeatedly in the circumferential direction inside the housing 120, the housing 120 is provided with a plurality of individual slots 121 repeated in the circumferential direction, and the thermoelectric module 140 may be inserted into each slot 121. For example, a plurality of separated thermoelectric modules 140 may respectively be inserted into individual slots 121.

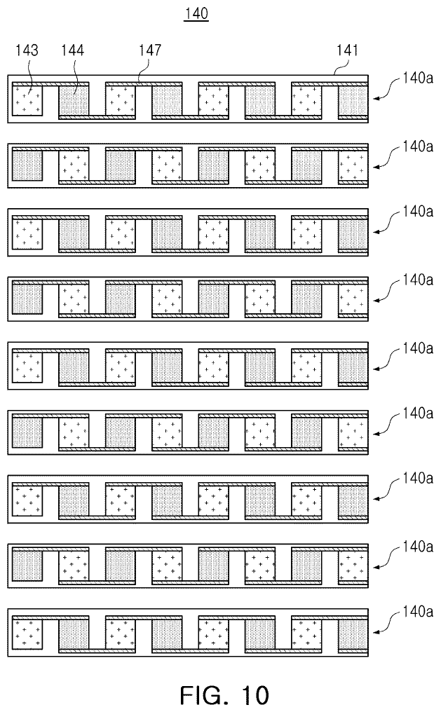

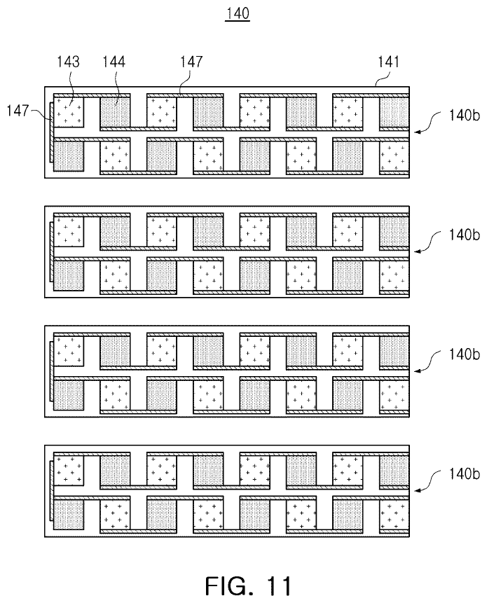

An example of the thermoelectric module 140 used in this embodiment is illustrated in FIG. 10 or FIG. 11. A plurality of separated thermoelectric modules 140 may be provided with a plurality of N-type pellets 143 and P-type pellets 144 repeated in a single row in the optical axis direction, to provide a structure 140a that is provided in plural, as illustrated in FIG. 10. Alternatively, the plurality of separated thermoelectric modules 140 may be provided with a plurality of N-type pellets 143 and P-type pellets 144 provided in two or more rows in a repeating manner, to provide a structure 140b that is provided in plural, in the optical axis direction as illustrated in FIG. 11.

The thermoelectric module 140 is mounted on a substrate 141 and has N-type pellets 143 and P-type pellets 144 repeated in the optical axis direction. The thermoelectric module 140 may include a connection electrode 147 connecting the N-type pellet 143 and the P-type pellet 144 to each other from the side. Additionally, the connection electrodes 147 may be alternately provided on both sides of the N-type pellets 143 and the P-type pellets 144 to connect the pellets in series.

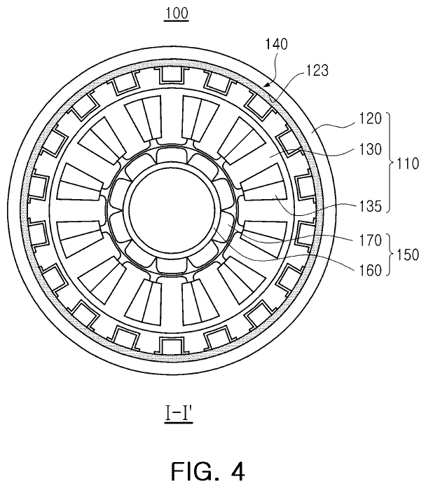

Referring to FIG. 4, the thermoelectric module 140 of this embodiment may be inserted into the slot 123 provided in the housing 120. The slots 123 may be provided continuously in the circumferential direction. Also, considering that a plurality of stator coils 135 are provided repeatedly in the circumferential direction inside the housing 120, the thermoelectric module 140 having a structure in which a plurality of N-type pellets 143 and P-type pellets 144 are repeatedly provided in the circumferential direction may be inserted into the housing 120.

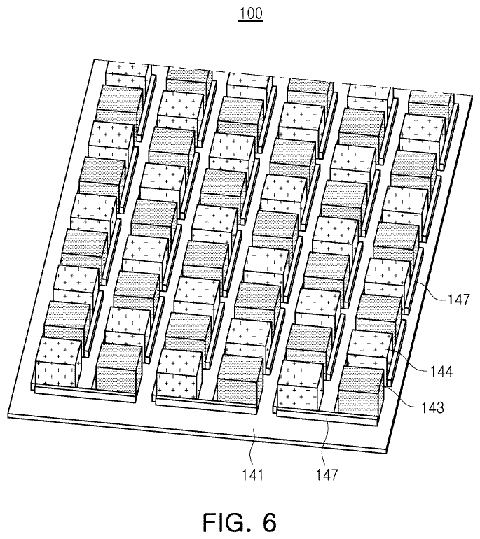

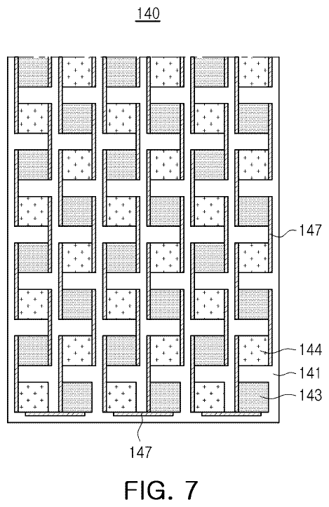

An example of the thermoelectric module 140 used in this embodiment is illustrated in FIGS. 6 and 7. The thermoelectric module 140 is mounted on the substrate 141 and has N-type pellets 143 and P-type pellets 144 repeated in the circumferential direction and the optical axis direction. The thermoelectric module 140 may include a connection electrode 147 connecting the N-type pellet 143 and the P-type pellet 144 to each other from the side. Additionally, the connection electrodes 147 may be alternately provided on both sides of the N-type pellets 143 and the P-type pellets 144 to connect the pellets in series. In this embodiment, the substrate 141 forms a structure that wraps approximately roundly in the circumferential direction, and may thus be a flexible substrate.

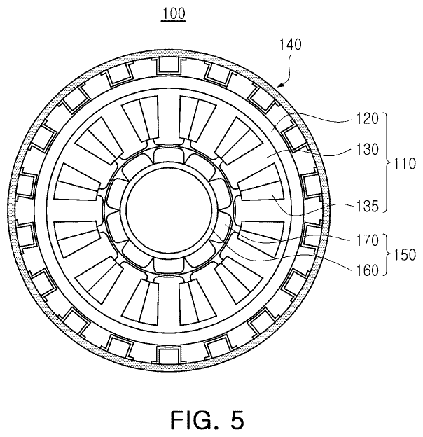

Referring to FIG. 5, the thermoelectric module 140 of this embodiment may be provided in a structure attached to the outer surface of the housing 120. Also, considering that a plurality of stator coils 135 is provided repeatedly in the circumferential direction inside the housing 120, a thermoelectric module 140 having a structure in which a plurality of N-type pellets 143 and P-type pellets 144 is repeatedly provided in the circumferential direction may be inserted into the housing 120.

An example of the thermoelectric module 140 used in this embodiment is illustrated in FIGS. 6 and 7. The thermoelectric module 140 is mounted on the substrate 141 and has N-type pellets 143 and P-type pellets 144 repeated in the circumferential direction and the optical axis direction. The thermoelectric module 140 may include a connection electrode 147 connecting the N-type pellet 143 and the P-type pellet 144 to each other from the side. Additionally, the connection electrodes 147 may be alternately provided on both sides of the N-type pellets 143 and the P-type pellets 144 to connect the pellets in series.

In this embodiment, the substrate 141 forms a structure that is substantially surrounded roundly in the circumferential direction, and thus the substrate 141 may be a flexible substrate.

In addition, since the N-type pellets 143 and the P-type pellets 144 are repeatedly provided in the circumferential direction and the optical axis direction, in the case of the pellets 143 or 144 provided at the start and end in the circumferential direction or the start and end in the optical axis direction, the connection electrode 147 may be connected to adjacent pellets in both the circumferential direction and the optical axis direction.

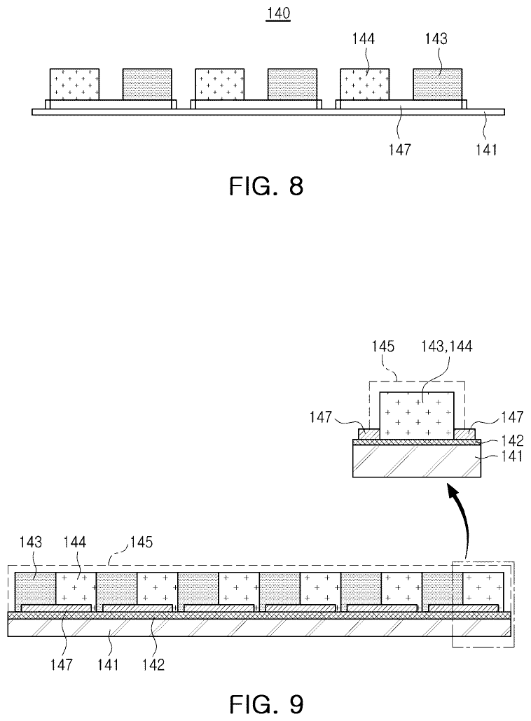

Referring to FIGS. 6-11, the thermoelectric module 140 may include a substrate 141, at least one pair of N-type pellets 143 and P-type pellets 144 alternately mounted on the substrate 141, and a connection electrode 147 connecting the N-type pellet 143 and the P-type pellet 144 to each other from the side.

In detail, the lower surfaces of the N-type pellet 143 and P-type pellet 144 are mounted on the substrate 141, and the sides of the N-type pellet 143 and the P-type pellet 144 may be electrically connected to each other by the connection electrode 147.

The thermoelectric module 140 may use ceramic or aluminum as the substrate 141. In this embodiment, to facilitate insertion of the thermoelectric module 140 into the housing 120 of the motor 100 or attachment of the thermoelectric module 140 to the outer side of the housing 120 and ensure durability, a rigid yet flexible material, such as an aluminum substrate 141, may be used.

Because the thermoelectric module 140 should be a dipole of the N-type pellet 143 and the P-type pellet 144 to implement thermoelectric power generation and the Peltier effect, the thermoelectric module 140 mounted on the motor may also be formed of N type (BiTe, etc.) and P type (SbTe, etc.).

The thermoelectric module 140 of this embodiment may be configured so that the connection electrode 147 connects the sides of the N-type pellet 143 and the P-type pellet 144 to significantly increase heat exchange efficiency.

The upper surface of the substrate 141 may be formed of an insulating material such as AlN, BN or the like and may be formed as a first insulating layer 142. Because the substrate 141, such as aluminum, has high thermal conductivity, the first insulating layer 142 may be desirably used (for example, in the case of nitride spraying, the thermal spray method may be used to secure adhesion to aluminum or the like).

Then, the N-type pellet 143 and the P-type pellet 144 may be mounted on the upper surface of the substrate 141 on which the first insulating layer 142 is formed.

In addition, after the connection electrode 147 connects the sides of the N-type pellet 143 and the P-type pellet 144, a second insulating layer 145 may be formed on the outer surfaces of the N-type pellet 143 and the P-type pellet 144 to be insulated externally, using a varnish material used in copper wire, or the like.

The connection electrode 147 may be printed on the substrate 141 or may be molded together with the substrate manufactured through a mold. The N-type pellet 143 and the P-type pellet 144 processed to fit the size of the manufactured connection electrode 147 may be inserted. The connection electrodes 147 are alternately provided on both sides of the N-type pellets 143 and the P-type pellets 144 to form an electrode structure in which the pellets are connected to each other in series.

After completing combining both sides of the N-type pellet 143 and the P-type pellet 144 with the connection electrode 147, for mechanical reinforcement, a metal solder joint may be formed by applying metal paste (Sn-Solder) to the gap that may be formed between the connection electrode 147 and the pellets 143 and 144.

In addition, after the N-type pellet 143 and the P-type pellet 144 is mounted on the substrate 141, the binder in the paste is removed. To ensure the stability of attachment of the pellets 143 and 144 and the connection electrode 147, a process of performing heat treatment at 200 degrees for 10 to 30 minutes may be added.

In addition, to ensure the electrical stability of the pellets 143 and 144 mounted in the overall completed thermoelectric module 140, for example, of the thermoelectric element, thermal/electrical stability may be secured by applying a varnish to the surface.

In addition, in the thermoelectric module 140 illustrated in FIGS. 6 and 7, the N-type pellets 143 and the P-type pellets 144 are mounted on the substrate 141 and are repeatedly provided in the circumferential direction and the optical axis direction. The connection electrodes 147 connecting the N-type pellets 143 and the P-type pellets 144 to each other from the side may be included. Additionally, the connection electrodes 147 may be alternately provided on both sides of the N-type pellets 143 and the P-type pellets 144 to connect the pellets in series.

In addition, because the N-type pellets 143 and the P-type pellets 144 are repeatedly provided in the circumferential direction and the optical axis direction, in the case of the pellets 143 or 144 provided at the start and end in the circumferential direction or the start and end in the optical axis direction, the connection electrode 147 may be connected to adjacent pellets in both the circumferential direction and the optical axis direction.

In this embodiment, the substrate 141 forms a structure that wraps approximately roundly in the circumferential direction, and thus the substrate 141 may be a flexible substrate.

In addition, the thermoelectric module 140 illustrated in FIG. 10 or FIG. 11 is divided into a plurality of thermoelectric modules 140 in which the N-type pellets 143 and the P-type pellets 144 are repeated in one row in the optical axis direction as illustrated in FIG. 10 to form a structure 140a. The structure 140a is provided in plural. Alternatively, as illustrated in FIG. 11, a structure 140b in which two or more rows of N-type pellets 143 and P-type pellets 144 are repeated in the optical axis direction may be provided in plural.

The thermoelectric module 140 may include the N-type pellets 143 and the P-type pellets 144 mounted on the substrate 141 and repeatedly provided in the optical axis direction, The substrate 141 may also include the connection electrodes 147 connecting the N-type pellets 143 and the P-type pellets 144 to each other from the side. Additionally, the connection electrodes 147 may be alternately provided on both sides of the N-type pellets 143 and the P-type pellets 144 to connect the pellets in series.

In addition, in the case of the structure 140b in which two or more rows of pellets illustrated in FIG. 11 are provided repeatedly, the N-type pellets 143 and the P-type pellets 144 are provided repeatedly in the circumferential direction and the optical axis direction. Therefore, in the case of the pellets 143 or 144 provided at the start and end in the circumferential direction or the start and end in the optical axis direction, the connection electrode 147 may be connected to adjacent pellets in both the circumferential direction and the optical axis direction.

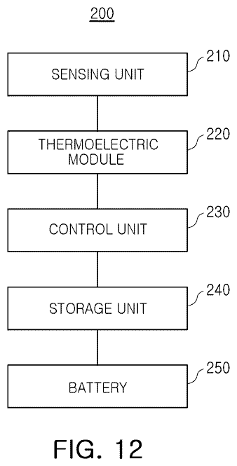

Referring to FIG. 12, a temperature control device 200 of a motor 100 according to an embodiment may include at least some of a sensing unit 210, a thermoelectric module 220 (same as ‘140’ in FIGS. 1-11), a control unit 230, a storage unit 240, and a battery 250.

The temperature control device 200 of a motor 100 according to this embodiment is a device that controls the thermoelectric module 220 to operate selectively in either thermoelectric power generation mode or Peltier mode (cooling mode), based on the temperature of a housing 120 (same as the housing 120 of the motor of FIGS. 1-11) detected by the sensing unit 210.

In detail, the temperature control device 200 of a motor according to an embodiment may include, as an example, the sensing unit 210 that detects the temperature of the housing 120 of a motor. The temperature control device 200 may further include the thermoelectric module 220 provided in the housing 120 to cool the motor. The temperature control device 200 may further include the control unit 230 that controls the operation of the thermoelectric module 220 according to the temperature detected by the sensing unit 210.

In addition, the control unit 230 may control the thermoelectric module 220 to selectively operate in either the thermoelectric power generation mode or the Peltier mode (cooling mode) based on the temperature of the housing 120 detected by the sensing unit 210.

The temperature control device 200 of the motor 100 may include a battery 250, and the battery may be a battery used to drive the motor or may be separately provided exclusively for the temperature control device of the motor.

The sensing unit 230 may be a thermometer and includes anything provided in any manner to sense the temperature of the housing.

In the storage unit, information necessary for the operation of the temperature control device 200 of a motor 100 may be stored or newly stored and may be updated or accumulated (according to time). For example, the set temperature (for example, a temperature selected from 90 to 110 degrees) may be stored as a boundary for selectively operating in either thermoelectric power generation mode or Peltier mode (cooling mode). The temperature of the motor housing sensed by the sensing unit may be continuously updated or stored cumulatively (according to time).

The temperature control device 200 of a motor 100 may further include a communication unit (including wired or wireless) that transmits the temperature of the housing sensed by the sensing unit to the storage unit.

The control unit 230 is controllably connected to the sensing unit 210, the thermoelectric module 220, the storage unit 240, and the battery 250 to receive or transmit electrical or control signals. The control unit 230 may command the thermoelectric module 220 to operate in power generation mode or cooling mode through information received from the sensing unit 210, the thermoelectric module 220, the storage unit 240, the battery 250, and the like.

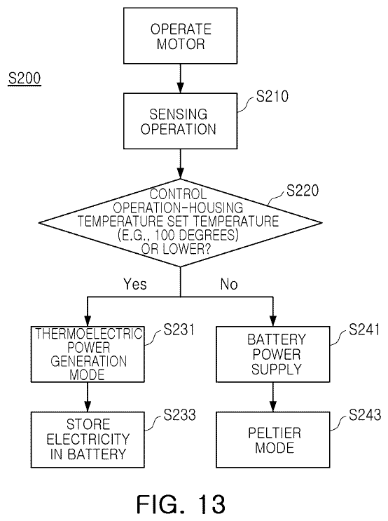

Referring to FIG. 13, a method (S200) of controlling the temperature of a motor according to an embodiment is illustrated.

The motor temperature control method (S200) of this embodiment may include a sensing operation (S210) that detects the temperature of a motor housing of a driving motor. The motor temperature control method (S200) may further include a control operation (S220) that compares the temperature of the housing detected in the sensing operation (S210) with the set temperature and selects and operates the thermoelectric module provided in the housing in either thermoelectric power generation mode or Peltier mode (cooling mode).

The sensing operation (S210) is an operation of measuring the temperature of the housing by the sensing unit 210 (for example, a temperature sensor such as a physical or electronic thermometer, or the like) provided in the housing. The temperature sensed in the sensing operation (S210) may be transmitted to the storage unit 240 by a wired or wireless communication unit according to a command from the control unit.

The control operation (S220) may determine whether the temperature sensed in the sensing operation (S210) is equal to or lower than the set temperature (for example, a temperature selected from 90 to 110 degrees) or exceeds the set temperature. The control operation (S220) may command the thermoelectric element 220 to operate in the power generation mode or cooling mode.

In addition, when the temperature detected in the sensing operation is equal to or lower than the set temperature (Yes in S220), the thermoelectric module may be operated in thermoelectric generation mode and the generated electricity may be commanded to be stored in the battery 250 (S231, S233). When the temperature detected in the sensing stage the set temperature (No in S220), the thermoelectric module may be commanded to operate in Peltier mode (cooling mode) using electricity stored in the battery (S241, 243).

On the other hand, both the sensing operation (S210) and the control operation (S220) of this embodiment may be executed by commands from the control unit 230.

Methods according to embodiments may be implemented in the form of program instructions that may be executed through various computer means and may be recorded on a computer-readable medium. A computer-readable medium may include program instructions, data files, data structures, and the like, singly or in combination. Program instructions recorded on a computer-readable medium may be specially designed and configured for the present disclosure or may be known and available to those having ordinary skill in the art of computer software.

Examples of computer-readable media include hardware devices specially configured to store and execute program instructions, such as ROM, RAM, flash memory, or the like. Examples of program instructions include high-level language code that may be executed by a computer using an interpreter, as well as machine language code, such as that produced by a compiler. The above-described hardware device may be configured to operate with at least one software module to perform the operations of the present disclosure, and vice versa.

The temperature control device 200 of a motor of this embodiment may include a storage unit 240. The storage unit 240 is a recording medium suitable for storing a motor temperature control method (S200) and may include magnetic media, such as hard disks, floppy disks, and magnetic tapes, optical media such as Compact Disk Read Only Memory (CD-ROM) and Digital Video Disk (DVD), magneto-optical media, such as floptical disk, and semiconductor memories such as flash memory, Erasable Programmable ROM (EPROM), or SSD manufactured based thereon.

The storage unit may be implemented by a non-volatile memory configured to store data regarding algorithms configured to control the operation of various components or software instructions that reproduce the algorithms. The storage unit may be further implemented by a processor configured to perform the operations described above or below using data stored in the corresponding memory. In this case, the memory and processor may be implemented as individual chips. Alternatively, the memory and processor may be implemented as a single chip integrated with each other. A processor may have the form of one or more processors.

The components of the motor temperature control method (S200) may exchange information through a wired or wireless communication network. For example, data may be exchanged using the network communication means provided in the vehicle, for example, Ethernet, Media Oriented Systems Transport (MOST), Flexray, Controller Area Network (CAN), Local Interconnect Network (LIN), Internet, LTE, 5G, Wi-Fi, Bluetooth, Near Field Communication (NFC), Zigbee, Radio Frequency (RF), low frequency (LF), or the like.

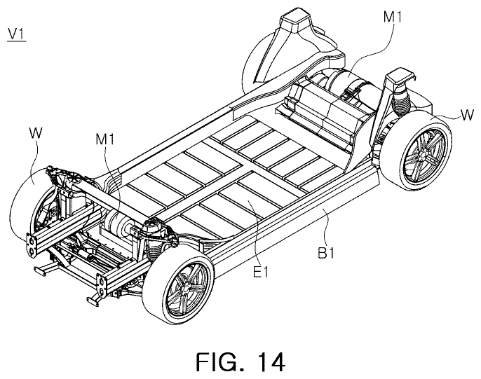

FIGS. 14, 15, and 16 are perspective views illustrating an example of a mobility device to which a motor is applied according to an embodiment.

Mobility devices V1 and V2 according to embodiments may at least include bodies B1 and B2, driving units W and P provided in the bodies B1 and B2, motors M1, M2, and 100 of this embodiment linked to the driving units W and P, and batteries E1 and E2 providing power to the motors. The motors M1 and M2 installed in the mobility devices V1 and V2 of the embodiments may be the motors 100 described with reference to FIGS. 1-11. Because the motor 100 as described with reference to FIGS. 1-11 may be installed, a detailed description of the structure thereof is omitted.

Referring to FIG. 14, the mobility device V1 in an embodiment may be a vehicle that may move on the ground. The vehicle (V1), a mobility device, may at least include a body B1, a wheel W that is a driving unit provided in the body B1, a motor M1 linked to the driving unit W, and a battery E1 that provides power to the motor.

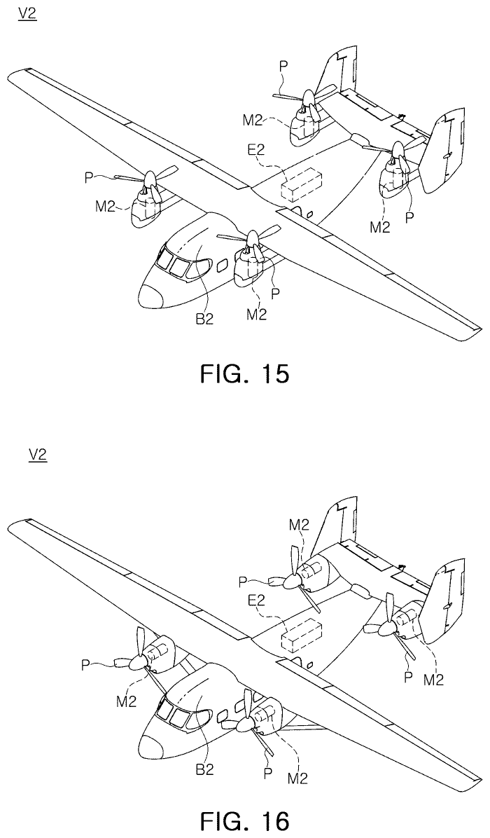

In addition, referring to FIGS. 15 and 16, the mobility device V2 in an embodiment may be air mobility that moves in the air. The air mobility V2 according to an embodiment may at least include a fuselage B2 as a body, a propellant P (for example, propeller) as a driving unit provided in the fuselage B2, a motor M2 linked to the propellant P, and a battery E2 that provides power to the motor.

FIG. 15 illustrates the position of the propeller P when the air mobility V2 takes off or lands, or hovers for turning at a specific point, or the like. FIG. 16 illustrates the position of the propeller P when the air mobility V2 moves, for example, when it travels. In detail, a structure is illustrated in which a direction of the propeller P that is the propulsion body of the air mobility V2 may be tilted, and the motor M2 that drives the propeller P may also be tilted accordingly.

In the case of the hovering mode illustrated in FIG. 15, the main wing and/or tail tilting propellant P pivots to be substantially perpendicular to the fuselage B2, and in the case of the cruising mode illustrated in FIG. 16, the main wing and/or tail non-tilting propellant P may pivot to be substantially parallel to the fuselage B2. The tilting of the main wing and/or tail tilting propellant P may be synchronized depending on the flight mode, and the tilting of respective propellants may be adjusted differently depending on the attitude control and flight situation in the same flight mode.

On the other hand, although detailed illustrations are omitted, a mobility device may be a device that moves through space related to the ground, underground, air, space, sea, and/or underwater, based on the space in which it moves. Above-ground or underground mobility devices may be provided in the form of, for example, vehicles, robots, and the like. Air and space mobility devices are called air mobility and, for example, may be provided in the form of a typical fixed-wing or rotary-wing aircraft, the recently actively developed Advanced Air Mobility (AAM), unmanned aerial vehicle or drone, a rocket, a means of transportation mounted on an artificial satellite, or the like. The sea or underwater mobility device may be, for example, a ship, a submarine, or the like. The mobility device is not limited to a specific space. The mobility device may be a mobile body that may move through all of the above-mentioned spaces, for example, a mobile body that may move between multiple spaces, and the mobility device may be, for example, an amphibious vehicle, a flying vehicle, or the like.

As set forth above, a motor for mobility devices according to an embodiment may have a motor structure that may actively control heat generation of the motor that may be generated by a stator coil. The motor may be used for cooling or power generation based on a heat generation state of the motor.

A motor according to an embodiment may be implemented by simple structural changes, and thus there is no major change compared to the related art, but performance thereof may be improved, which has an effect of substantially reducing costs.

The effects of the present disclosure are not limited to those described above, and other effects not mentioned should be clearly recognized by those having ordinary skill in the art from the description below.

While example embodiments have been illustrated and described above, it should be apparent to those having ordinary skill in the art that modifications and variations could be made without departing from the scope of the present disclosure as defined by the appended claims.

What is claimed is:

1. A motor comprising:
a stator provided inside a housing and having a plurality of stator coils repeatedly disposed in a circumferential direction; and
a thermoelectric module provided in the housing and configured to cool the plurality of stator coils,
wherein the thermoelectric module includes a substrate, at least one pair of an N-type pellet and a P-type pellet alternately mounted on the substrate, and a connection electrode configured to connect the N-type pellet and the P-type pellet to each other on a side.

2. The motor of claim 1, further comprising a rotor provided inside the stator, rotatable about a rotation axis, and having a magnetic body configured to interact with at least one of the plurality of stator coils and generate rotational force.

3. The motor of claim 1, further comprising an insulating layer provided on an upper surface of the substrate,
wherein the N-type pellet and the P-type pellet are mounted on the upper surface of the substrate.

4. The motor of claim 1, wherein the N-type pellet and the P-type pellet are covered with an insulating layer except for portions thereof connected to the connection electrode.

5. The motor of claim 1, wherein the N-type pellet, the P-type pellet, and the connection electrode are provided with a metal solder joint therebetween.

6. The motor of claim 1, wherein the thermoelectric module includes the N-type pellet and the P-type pellet alternately mounted on the substrate in the circumferential direction and an optical axis direction.

7. The motor of claim 6, wherein a plurality of connection electrodes is alternately provided on both sides of the N-type pellet and the P-type pellet and is connected in series.

8. The motor of claim 1, wherein the thermoelectric module includes the N-type pellet and the P-type pellet mounted on a plurality of separated substrates,
wherein the plurality of separated substrates is disposed at regular intervals in the circumferential direction.

9. The motor of claim 1, wherein the thermoelectric module is inserted into a slot provided in the housing.

10. The motor of claim 1, wherein the thermoelectric module is attached to an outer surface of the housing.

11. The motor of claim 10, wherein the substrate is a flexible substrate.

12. A method of controlling cooling of a motor, the method comprising:
performing a sensing operation by detecting a temperature of a housing of the motor; and
performing a control operation by
comparing the temperature of the housing detected in the sensing operation with a set temperature, and
operating a thermoelectric module provided in the housing by selecting either a thermoelectric power generation mode or a Peltier mode as a cooling mode.

13. The method of claim 12, wherein the set temperature is a temperature selected from 90 to 110 degrees.

14. The method of claim 12, further comprising:
operating the thermoelectric module in the thermoelectric power generation mode when the temperature detected in the sensing operation is equal to or lower than the set temperature, and
operating the thermoelectric module in the Peltier mode as the cooling mode when the temperature detected in the sensing operation exceeds the set temperature.

15. The method of claim 14, further comprising:
storing, in a battery, electricity generated when the control unit operates the thermoelectric module in the thermoelectric power generation mode, and
using the electricity stored in the battery when the control unit operates the thermoelectric module in the Peltier mode as the cooling mode.

16. A mobility device comprising:
a body;
at least one driving unit provided on the body;
a battery provided in the body; and
the motor of claim 1, configured to be connected to the battery and provide driving force to the at least one driving unit.
